(19) United States
(12) Patent Application Publication
(10) Pub. No.: US 2005/0247946 A1
(43) Pub. Date: Nov. 10, 2005

(54) Organic light emitting device and method of fabricating the same

(76) Inventor: Hyun-Eok Shin, Seongnam-si (KR)

Correspondence Address: MCGUIREWOODS, LLP, 1750 TYSONS BLVD, SUITE 1800, MCLEAN, VA, 22102, US

(21) Appl. No.: 11/070,153

(22) Filed: Mar. 3, 2005

(30) Foreign Application Priority Data
May 10, 2004 (KR) 2004-32844

(51) Int. Cl. H01L 29/08; H01L 35/24; H01L 51/00; H01L 29/18; H01L 33/00; H01L 29/20; H01L 29/22

(52) U.S. Cl. 257/88; 257/89

(57) ABSTRACT

An organic light emitting device may includes a pixel electrode formed on a substrate and having a reflecting layer and a transparent electrode layer, a pixel defining layer having an opening to expose a portion of the pixel electrode, an organic layer formed on the opening, and an upper electrode formed on an entire surface of the substrate. The reflecting layer may be a material having excellent reflection efficiency and having an oxidation-reduction potential difference of about 0.3 or less with respect to the transparent electrode layer.

### CROSS-REFERENCE TO RELATED APPLICATION

This application claims priority to and the benefit of Korean Patent Application No. 2004-32844, filed May 10, 2004, which is incorporated herein by reference in its entirety.

### BACKGROUND OF THE INVENTION

(a) Field of the Invention

The present invention relates to an organic light emitting device and, more particularly, to an organic light emitting device capable of preventing galvanic reaction in a reflective pixel electrode.

(b) Description of the Related Art

Generally, an organic light emitting device is a light emitting device that emits light when electrons and holes are injected from an electron injection electrode (cathode) and a hole injection electrode (anode) to an emission layer and excitons created by recombination of the injected electrons and holes transition from an excited state to a ground state.

The use of this principle eliminates the need for a separate light source that was necessary in a conventional thin film liquid crystal display device, thus reducing the volume and weight of the display device.

Organic light emitting devices can be either passive matrix organic light emitting devices or active matrix organic light emitting devices, depending on how they are driven.

The passive matrix organic light emitting device is easy to manufacture because of its simple configuration. However, the passive matrix organic light emitting device has high power consumption and it is difficult to manufacture large-sized passive matrix organic light emitting displays. Furthermore, the aperture ratio degrades as the number of wirings increases.

Accordingly, passive matrix organic light emitting devices are typically used for small-sized display devices and active matrix organic light emitting devices are typically used in large-sized display devices.

A typical top emitting organic light emitting device is made of a reflecting electrode having an excellent reflection characteristic on one side. A reflective conductive material having a proper work function may be used as the reflecting electrode. However, because there is no suitable single material so far that satisfies such characteristics, the reflecting electrode is generally fabricated in a multi-layer structure in which a separate reflecting layer is formed and an electrode material having a different conductivity is formed thereon. When employing the multi-layer structure, galvanic corrosion at an interface between the metals should not be overlooked.

Galvanic corrosion occurs when the reduction-oxidization potential difference between two different kinds of metals causes voltage generation and current flow when the two metals are proximate. Among such different metals in electrical contact, the highly active (low potential) metal acts as an anode and the relatively less active (high potential) metal acts as a cathode, wherein the high or low active nature is due to a difference in work function at an interface between the two metals.

The potential difference between the two metals may cause corrosion at point of contact of the two metals when the two metals are exposed to a corrosive solution. The highly active anode typically corrodes at a faster rate compared to a sole anode while the lower active cathode typically corrodes at a lower rate.

As shown in FIG. 1A, a top emitting organic light emitting diode can have a structure in which a reflecting layer 1110a and a transparent electrode layer 1110b are sequentially deposited on a substrate 100 as a pixel electrode 110, and an organic layer 130 and an upper electrode 140 are sequentially formed on the pixel electrode 110.

In the top emitting organic light emitting diode having such a structure, the reflecting layer 110a can be formed by uniformly depositing a metal material having excellent reflection efficiency on the substrate 100 using, for example, sputtering or vacuum deposition. As a conventional reflecting layer, an active metal such as aluminum or an alloy thereof has been employed.

Next, so that external incident light is reflected by the reflecting layer 110a, a transparent electrode material is deposited on the reflecting layer 1110a to form the transparent electrode layer 10b. The transparent electrode layer 10b is then patterned to form the pixel electrode 110. Indium tin oxide (ITO) or indium zinc oxide (IZO) can, for example, be used as the transparent electrode material.

A pixel defining layer 120 is then formed at both sides of the pixel electrode 110 to define a pixel region. An emission layer, an organic layer 130 that has the capability of transporting charges such as electrons and holes, and an upper electrode 140 are formed thereon to complete the top emitting organic light emitting diode.

In the process of fabricating the light emitting diode as described above, patterning the pixel electrode 110 is typically achieved by successively performing a photolithography process and an etching process. Specifically, a photoresist pattern is formed on the transparent electrode layer 110b and is subjected to typical exposing and developing processes. Thereafter, the transparent electrode layer 110b and the reflecting layer 1110a are sequentially etched using the pattern as a mask.

Wet or dry etching may be used as the etching process. In wet etching, a region to be etched is coated or sprayed with a strong acid solution such as HF, HNO₃, H₂SO₄, or the like to obtain a desired pattern. This strong acid is also used in cleaning and stripping processes following the etching. Alternatively, a strong acid or strong base chemical such as HNO₃, HCl, H₃PO₄, H₂O₂, NH₄OH, or the like is used.

The strong acid and strong base chemical substances, that are used in the etching, cleaning and stripping processes, are in direct contact with the transparent electrode layer 1110b and the reflecting layer 110a used as the pixel electrode 110, which leads to galvanic corrosion at the interface between the transparent electrode layer 110b and the reflecting layer 1110a, as shown in FIG. 1B [J. E. A. M. van den Meerakker and W. R. ter Veen, J. Electrochem. Soc., vol. 139, no. 2, 385 1992].

In particular, considering that aluminum, an alloy thereof, or the like (used for the reflecting layer) corrodes rapidly to easily form a metal oxide layer 110c such as Al₂O₃ even when exposed to the air, the formation of the metal oxide layer 110c due to galvanic corrosion can be a very serious problem. In particular, if some of the chemical substances remain at the interface between the transparent electrode layer 10b and the reflecting layer 110a, severe problems can occur. For example, corrosion can be accelerated by the combination of galvanic corrosion and crevice corrosion.

Galvanic corrosion can spread along the interface between the transparent electrode layer 110b and the reflecting layer 110a and can rapidly increase contact resistance between the electrodes, resulting in an unstable distribution of the resistance. As a result, when the top emitting organic light emitting device operates, brightness non-uniformity can occur in which some pixels are bright while some are dark. Thus, the image quality can be greatly degraded, as in FIG. 2.

In order to solve the problems caused by the galvanic phenomenon as described above, Japanese Patent Laid-open No. 2003-140191 (SAMSUNG ELECTRONICS Co. Ltd.) (which is hereby incorporated by reference in its entirety) presents a method for suppressing galvanic reaction at an interface between an aluminum alloy and ITO. Specifically, there is disclosed a method of forming a pixel electrode having a structure in which a passivation layer of, for example, molybdenum-tungsten (MoW) is deposited to a thickness of about 3000 Å on an aluminum-neodymium (AlNd) layer, and a transparent electrode layer is deposited on the passivation layer.

However, when the pixel electrode in the above-referenced patent is applied to the top emitting organic light emitting device, the MoW is formed to a thickness of 3000 Å. This lowers the reflectivity of light emitted from the organic layer, and in turn the lowered reflectivity degrades the brightness of the top emitting organic light emitting device.

### SUMMARY OF THE INVENTION

The present invention provides, for example, a top emitting organic light emitting is device and method of fabricating the same, in which galvanic phenomena are prevented at interfaces between a transparent electrode material and a metal material, without degrading brightness of the display.

Further, the present invention provides a top emitting organic light emitting device having uniform brightness and method of fabricating the same.

In an exemplary embodiment of the present invention, an organic light emitting device may include a pixel electrode formed on a substrate having a reflecting layer and a transparent electrode layer, a pixel defining layer having an opening to expose a portion of the pixel electrode, an organic layer formed on the opening, and an upper electrode formed on an entire surface of the insulating substrate. The reflecting layer may be formed of a material having excellent reflection efficiency and having an oxidation-reduction potential difference of about 0.3 or less with respect to the transparent electrode layer.

Preferably, the reflecting layer may include an Al—Ni alloy. The reflecting layer may preferably include Ni of 10% or less.

### BRIEF DESCRIPTION OF THE DRAWINGS

FIG. 1A is a cross-sectional view illustrating a conventional top emitting organic light emitting device.

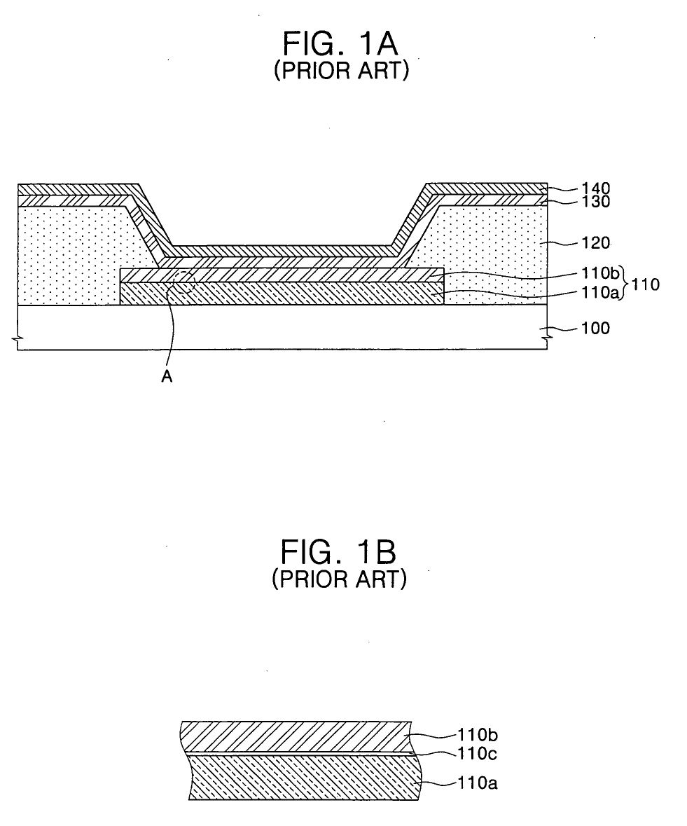

FIG. 1B is an enlarged cross-sectional view of the portion A in FIG. 1A, showing that an oxide layer is formed at an interface between a reflecting layer and a transparent electrode.

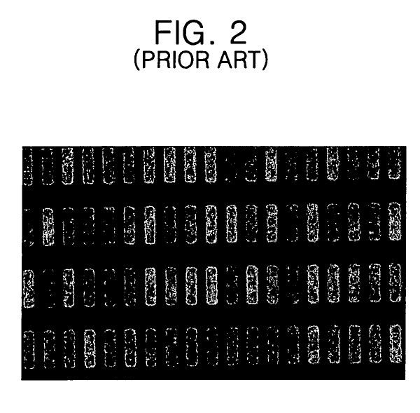

FIG. 2 illustrates the non-uniformity in brightness of a conventional organic light emitting device.

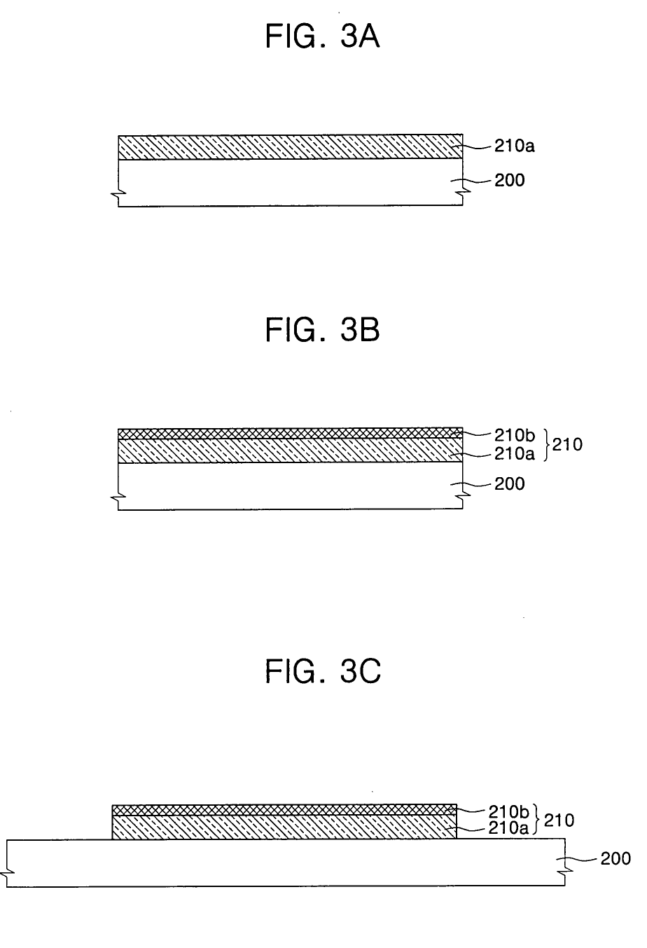

FIGS. 3A, 3B, 3C, 3D, and 3E are process cross-sectional views illustrating a method of fabricating a top emitting organic light emitting device according to an embodiment of the present invention.

FIG. 4 illustrates the reflectivity depending on a structure of a pixel electrode.

FIG. 5 illustrates the uniformity in brightness of an organic light emitting device according to an embodiment of the present invention.

### DETAILED DESCRIPTION

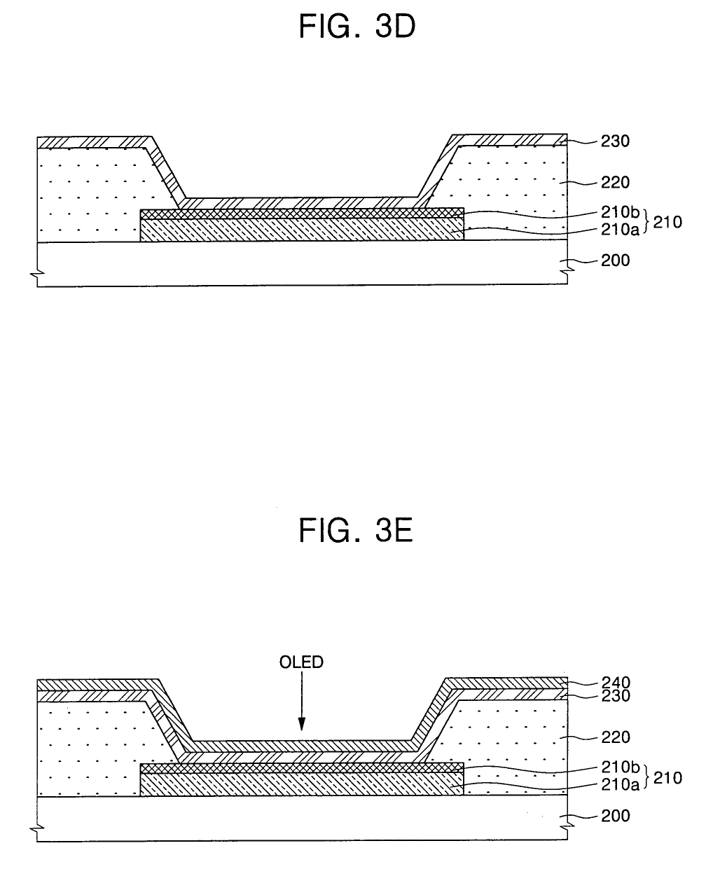

As shown in FIG. 3A, a reflecting layer 210a may be formed (of a metal material having excellent reflection efficiency) on an insulating substrate 200. The reflecting layer 210a may be formed of a material having excellent reflection efficiency and having an oxidation-reduction potential (a.k.a., Redox Potential) difference of about 0.3 or less with respect to a pixel electrode. This may help to prevent galvanic reaction with the pixel electrode that is to be formed. More preferably, the reflecting layer 210a may be formed of an Al—Ni alloy.

It is preferable that the Al—Ni alloy used for the reflecting layer 210a be an Al alloy containing nickel (Ni) of about 10% or less.

The reflecting layer 210a may also be formed by a typical method, such as radio frequency (RF) sputtering, direct current (DC) sputtering, ion beam sputtering, vacuum deposition, or the like.

Further, either a glass substrate or a plastic substrate may be used as the substrate 200.

As shown in FIG. 3B, after the reflecting layer 210a is formed, a transparent electrode layer 210b may be formed on the reflecting layer 210a. Indium tin oxide (ITO) or indium zinc oxide (IZO) may be used as the transparent electrode layer 210b. The oxidation-reduction potential (Redox Potential) of the ITO may be about −0.82.

The transparent electrode layer 210b may also be formed to a thickness of about 20 Å to about 300 Å by, for example, sputtering or vacuum deposition.

As shown in FIG. 3C, in order to form a pixel electrode of the organic light emitting device, photoresist may be coated on the transparent electrode layer 210b, and may be subjected to typical baking, exposing, and developing processes to form a photoresist pattern.

The reflecting layer 210a and the transparent electrode layer 210b may be etched using the photoresist pattern as a mask to form a pixel electrode 210 of the organic light emitting device.

As shown in FIG. 3D, a pixel defining layer 220 having an opening to expose a portion of the pixel electrode 210 may be formed on the pixel electrode 210 to define an emission region of the organic light emitting diode.

After the pixel defining layer 220 is formed, an organic layer 230 may be formed on the pixel electrode 210 over an entire surface of the substrate 200. The organic layer 230 may be formed of several layers according to its functionality. Generally, it can be formed in a multilayer structure including (in addition to an emission layer) at least one of the following: a hole injecting layer (HIL), a hole transporting layer (HTL), a hole blocking layer (HBL), an electron transporting layer (ETL), and an electron injecting layer (EIL).

The emission layer is a layer that emits, by itself, light of a specific wavelength according to a recombination theory of electrons and holes injected from cathode and anode of the organic light emitting diode. The hole injecting layer, the hole transporting layer, the hole blocking layer, the electron transporting layer, the electron injecting layer, and the like having charge transporting capability are further selectively inserted between each electrode and the emission layer to obtain high luminous efficiency.

When the pixel electrode 210 in the top emitting organic light emitting diode according to the present invention acts as an anode electrode, a subsequently formed upper electrode acts as a cathode electrode. The hole injecting layer and the hole transporting layer of the organic layer to be added may be positioned between the pixel electrode 210 and the emission layer 230. The hole blocking layer, the electron transporting layer, and the electron injecting layer may be positioned between the emission layer 230 and the upper electrode.

The organic layer 230 including such an emission layer may be formed by a wet coating method such as spin coating, deep coating, spray, screen printing, or inkjet printing coating in a solution state, or a dry coating method such as sputtering or vacuum deposition.

As shown in FIG. 3E, an upper electrode 240 is formed on the organic layer 230 to form an organic light emitting diode (OLED). The upper electrode 240 may be formed by forming a metal material having a low work function such as magnesium (Mg), calcium (Ca), aluminum (Al) or an alloy thereof to such a thickness that light may pass through the metal material, or by depositing a transparent conductive material such as ITO or IZO.

Although not shown, the organic light emitting diode (OLED) may then be encapsulated using an upper substrate.

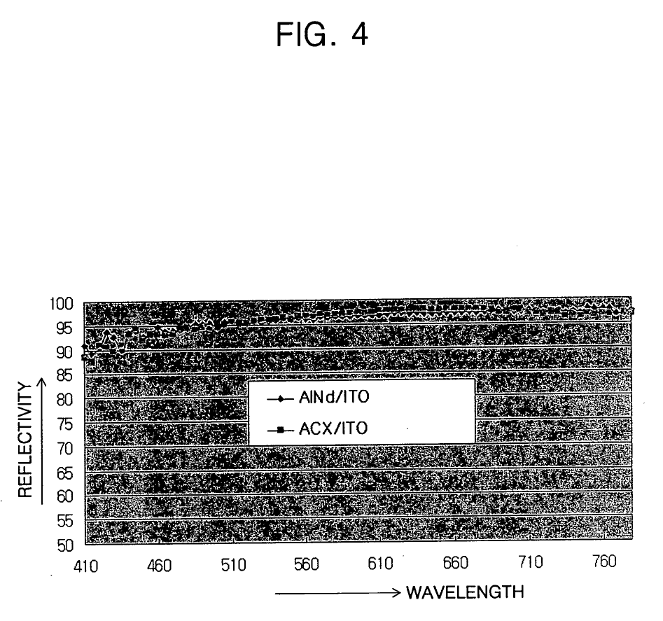

As shown in FIG. 4, the reflectivity when AlNd/ITO is applied as the pixel electrode of the top emitting organic light emitting device and the reflectivity when Al—Ni/ITO is applied may be similar to each other.

Even though the Al—Ni may be used as the reflecting layer of the pixel electrode in the top emitting organic light emitting device, it may not influence the reflectivity of the pixel electrode.

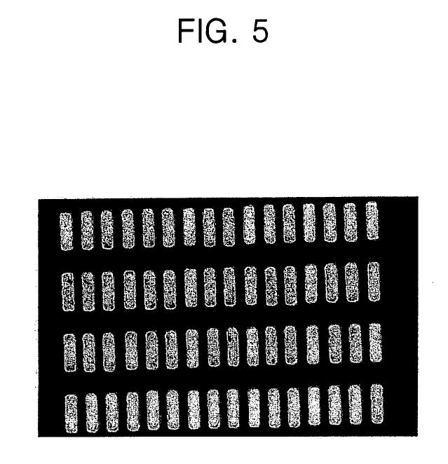

As shown in FIG. 5, the organic light emitting device including the pixel electrode composed of the reflecting layer, the galvanic protecting passivation layer, and the transparent electrode layer can realize a high-definition image showing uniform brightness between respective pixels.

In the operation of the organic light emitting device that is formed through the processes as described above, light emitted from the organic layer may be emitted to the exterior through the upper electrode 240. It may also be reflected by the reflecting layer 210a of the pixel electrode 210, and may then be emitted to the exterior through the upper electrode 240.

Thus, it may be possible to form an organic light emitting device that displays a high-definition image showing uniform brightness between respective pixels, as in FIG. 5. This may be accomplished by forming the reflecting layer 210a using a material having excellent reflection efficiency and having an oxidation-reduction potential (Redox Potential) difference of about 0.3 or less with respect to the transparent electrode 210b to prevent galvanic reaction at the interface between the reflecting layer 210a and the transparent electrode layer 210b.

The present invention may be capable of providing an organic light emitting device and method of fabricating the same. In such a device galvanic reaction occurring at the interface between the reflecting layer and the transparent electrode layer may be prevented.

The present invention is also capable of providing the organic light emitting device and method of fabricating the same, in which a high-definition image showing uniform brightness between respective pixels may be realized.

Although the present invention has been described with reference to certain exemplary embodiments thereof, a variety of changes may be made to these embodiments without departing from the scope of the present invention.

1. An organic light emitting device, comprising:
a pixel electrode formed on a substrate and having a reflecting layer and a transparent electrode layer;
a pixel defining layer having an opening to expose a portion of the pixel electrode;
an organic layer formed on the opening; and
an upper electrode formed on substantially an entire surface of the substrate,
wherein the reflecting layer comprises a material having excellent reflection efficiency and having an oxidation-reduction potential difference of about 0.3 or less with respect to the transparent electrode layer.

2. The device of claim 1, wherein the reflecting layer comprises an Al—Ni alloy.

3. The device of claim 1, wherein the reflecting layer comprises an Al—Ni alloy containing nickel (Ni) of about 10% or less.

4. The device of claim 1, wherein the transparent electrode layer is formed of indium tin oxide (ITO) or indium zinc oxide (IZO).

5. The device of claim 1, wherein the organic layer comprises an emission layer (EML), and at least one layer selected from a group of a hole injecting layer (HIL), a hole transporting layer (HTL), a hole blocking layer (HBL), an electron transporting layer (ETL), and an electron injecting layer (EIL).

6. The device of claim 1, wherein the substrate comprises at least one of glass and plastic.

7. A method of fabricating an organic light emitting device, comprising:
sequentially depositing a reflecting layer and a transparent electrode layer on a substrate;
simultaneously patterning the reflecting layer and the transparent electrode layer to form a pixel electrode;
forming a pixel defining layer having an opening exposing a portion of the pixel electrode;
forming an organic layer on the opening; and
forming an upper electrode on substantially an entire surface of the substrate,
wherein the reflecting layer comprises a material having excellent reflection efficiency and having an oxidation-reduction potential difference of about 0.3 or less with respect to the transparent electrode layer.

8. The method of claim 7, wherein the reflecting layer comprises an Al—Ni alloy.

9. The method of claim 7, wherein the reflecting layer is formed by at least one of radio frequency (RF) sputtering, direct current (DC) sputtering, ion beam sputtering, and vacuum deposition.
